(19) United States
(12) Patent Application Publication
(10) Pub. No.: US 2015/0285867 A1
(43) Pub. Date: Oct. 8, 2015

(54) MODEL-BASED DIAGNOSIS FOR BATTERY VOLTAGE

(71) Applicant: FORD GLOBAL TECHNOLOGIES, LLC, Dearborn, MI (US)

(72) Inventors: Xu WANG, Dearborn, MI (US); Xiaoguang CHANG, Northville, MI (US)

(73) Assignee: FORD GLOBAL TECHNOLOGIES, LLC, Dearborn, MI (US)

(21) Appl. No.: 14/247,553

(22) Filed: Apr. 8, 2014

(51) Int. Cl. G01R 31/36

(52) U.S. Cl. CPC G01R 31/3648; G01R 31/3606

(57) ABSTRACT

A hybrid or electric vehicle includes a traction battery. A battery measurement diagnostic system compares a measured voltage and an estimated voltage. The estimated voltage is based on impedance parameter estimates and an equivalent circuit model of a battery. When a magnitude of a difference between the measured and estimated voltages is greater than a threshold, the impedance parameter estimates are based on impedance parameter estimates from a previous time step. If the magnitude exceeds the threshold for a predetermined number of time steps, a voltage measurement diagnostic flag is output. The logic minimizes the impact of voltage measurement spikes on estimated quantities and may indicate the condition to an operator.

### TECHNICAL FIELD

This application generally relates to diagnosing battery voltage measurements.

### BACKGROUND

Electric and hybrid-electric vehicles include a traction battery to provide and store energy for vehicle propulsion. The traction battery may include a plurality of individual cells. The voltage of the cells and/or traction battery may be measured and used for calculating other battery characteristics such as state of charge (SOC) and power capability. The measured voltage may also be used to prevent overcharging and over-discharging of the traction battery.

Since the measured voltage is a key quantity for controlling the traction battery, many systems diagnose battery voltage measurement issues. The voltage measurement may be made through a controller. The controller may have appropriate circuitry for scaling and converting the voltage. Various resistance and capacitance values may be configured to filter and scale the voltage. The filtered and scaled voltage may be an input to an Analog-to-Digital (AD) converter for conversion to a digital value. Any of these components may develop an issue that renders the measured voltage value incorrect. Possible issues may include short circuiting or intermittent connection of a component. This may cause sudden changes in the measured voltage value.

### SUMMARY

A vehicle includes a traction battery having a plurality of cells and at least one controller. The at least one controller is programmed to output impedance parameters based on a measured voltage at a plurality of time steps while a magnitude of a difference between the measured voltage and an impedance parameter based estimated voltage is less than a predetermined value, and otherwise, output impedance parameters based on impedance parameter estimates from a selected previous one of the time steps. The controller may be further programmed to, in response to the magnitude of the difference between the measured voltage and the impedance parameter based estimated voltage being greater than the predetermined value for greater than a predetermined number of time steps, output a diagnostic flag. The selected previous one of the time steps may be a most recent time step in which the magnitude of the difference between the measured voltage and the impedance parameter based estimated voltage is less than the predetermined value. The at least one controller may be further programmed to output impedance parameters further based on a measured current. The at least one controller may be further programmed to output impedance parameters based on impedance parameter estimates from the selected previous one of the time steps while the magnitude is greater than the predetermined value and the difference indicates a voltage change different than an expected voltage change indicated by a change in the measured current.

A vehicle includes a traction battery, having a plurality of cells, and at least one controller. The at least one controller is programmed to, in response to a magnitude of a difference between a measured cell voltage and an impedance parameter based estimated cell voltage at each of a plurality of time steps being greater than a predetermined value for a predetermined number of the time steps, output a diagnostic flag. The predetermined number of the time steps may be non-consecutive. The at least one controller may be further programmed to estimate impedance parameters at the plurality of time steps based on the measured cell voltage while the difference is less than the predetermined value. The at least one controller may be further programmed to estimate impedance parameters at the plurality of time steps based on impedance parameters from a selected previous one of the time steps while the difference is greater than the predetermined value. The selected previous one of the time steps may be a most recent time step in which the difference is less than the predetermined value. The at least one controller may be further programmed to estimate impedance parameters and the estimated cell voltage based on an equivalent circuit model of the cells. The at least one controller may be further programmed to output the diagnostic flag further in response to the difference indicating a voltage change different than an expected voltage change indicated by a change in a measured current for the predetermined number of the time steps.

A method of battery voltage estimation includes measuring, by a controller, a voltage at a plurality of time steps, outputting an estimated voltage based on impedance parameter estimates while a difference magnitude between the voltage and the estimated voltage is less than a predetermined value, and outputting the estimated voltage based on impedance parameters from a selected previous one of the time steps while the difference magnitude is greater than the predetermined value. The method may further include outputting a diagnostic flag in response to the difference magnitude being greater than the predetermined value for a predetermined number of the time steps. The impedance parameter estimates may be based on the voltage while the difference magnitude is less than the predetermined value. The method may further include measuring a battery current, wherein the impedance parameter estimates are further based on the battery current while the difference magnitude is less than the predetermined value. The method may further include outputting the estimated voltage based on impedance parameter estimates from the selected previous one of the time steps while the difference magnitude is greater than the predetermined value and the difference indicates a voltage change different than an expected voltage change indicated by a change in the battery current. The selected previous one of the time steps may be a most recent one of the time steps in which the difference magnitude is less than the predetermined value. The method may further include estimating the impedance parameters and estimating the voltage at the plurality of time steps based on an equivalent circuit model of the battery. The method may further comprise outputting a diagnostic flag in response to at least one of a battery open-circuit voltage being less than the voltage for a predetermined number of time steps during discharging and the battery open-circuit voltage being greater than the voltage for a predetermined number of time steps during charging.

### BRIEF DESCRIPTION OF THE DRAWINGS

FIG. 1 is a diagram of a hybrid vehicle illustrating typical drivetrain and energy storage components.

FIG. 2 is a diagram of a possible battery pack arrangement comprised of multiple cells, and monitored and controlled by a Battery Energy Control Module.

FIG. 3 is a diagram of an example battery cell equivalent circuit.

FIG. 4 is a graph that illustrates a possible open-circuit voltage (Voc) vs. battery state of charge (SOC) relationship for a typical battery cell.

FIG. 5 is graph illustrating a possible behavior of current and measured voltage over time.

FIG. 6 is a graph illustrating a possible behavior of current and measured voltage within a time interval selected from the graph of FIG. 5.

FIG. 7 is a flowchart illustrating a possible sequence of operations for detecting a voltage measurement diagnostic.

FIG. 8 is a block diagram illustrating a possible system for diagnosing a voltage measurement condition.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present invention. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

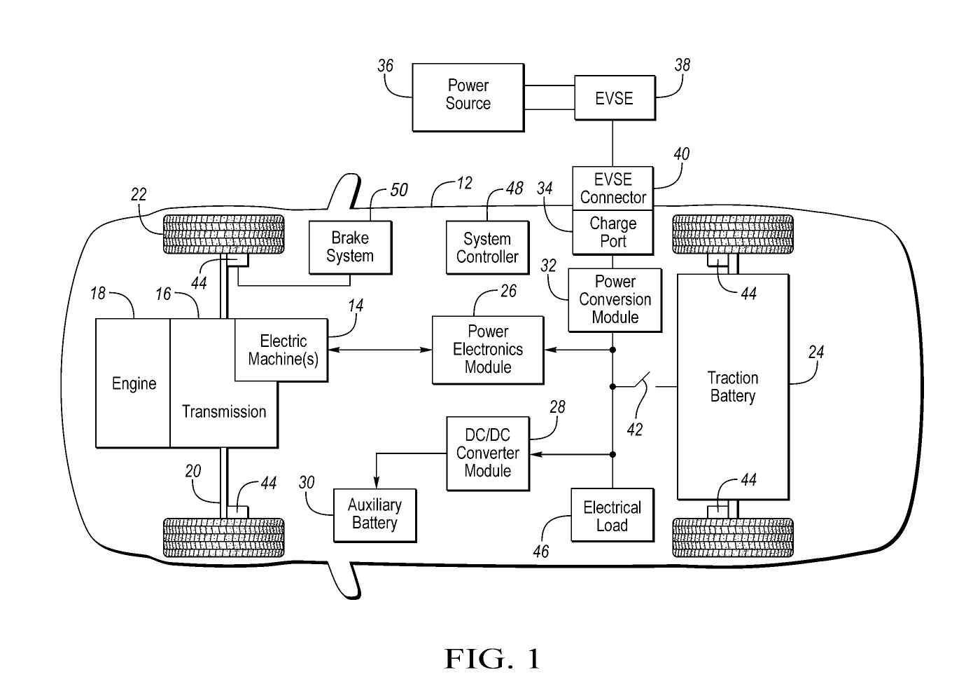

FIG. 1 depicts a typical plug-in hybrid-electric vehicle (HEV). A typical plug-in hybrid-electric vehicle 12 may comprise one or more electric machines 14 mechanically connected to a hybrid transmission 16. The electric machines 14 may be capable of operating as a motor or a generator. In addition, the hybrid transmission 16 is mechanically connected to an engine 18. The hybrid transmission 16 is also mechanically connected to a drive shaft 20 that is mechanically connected to the wheels 22. The electric machines 14 can provide propulsion and deceleration capability when the engine 18 is turned on or off. The electric machines 14 also act as generators and can provide fuel economy benefits by recovering energy that would normally be lost as heat in the friction braking system. The electric machines 14 may also reduce vehicle emissions by allowing the engine 18 to operate at more efficient speeds and allowing the hybrid-electric vehicle 12 to be operated in electric mode with the engine 18 off under certain conditions.

A traction battery or battery pack 24 stores energy that can be used by the electric machines 14. A vehicle battery pack 24 typically provides a high voltage DC output. The traction battery 24 is electrically connected to one or more power electronics modules. One or more contactors 42 may isolate the traction battery 24 from other components when opened and connect the traction battery 24 to other components when closed. The power electronics module 26 is also electrically connected to the electric machines 14 and provides the ability to bi-directionally transfer energy between the traction battery 24 and the electric machines 14. For example, a typical traction battery 24 may provide a DC voltage while the electric machines 14 may use a three-phase AC current to function. The power electronics module 26 may convert the DC voltage to a three-phase AC current used by the electric machines 14. In a regenerative mode, the power electronics module 26 may convert the three-phase AC current from the electric machines 14 acting as generators to the DC voltage used by the traction battery 24. The description herein is equally applicable to a pure electric vehicle. For a pure electric vehicle, the hybrid transmission 16 may be a gear box connected to an electric machine 14 and the engine 18 may not be present.

In addition to providing energy for propulsion, the traction battery 24 may provide energy for other vehicle electrical systems. A vehicle may include a DC/DC converter module 28 that converts the high voltage DC output of the traction battery 24 to a low voltage DC supply that is compatible with other vehicle loads. Other high-voltage electrical loads 46, such as compressors and electric heaters, may be connected directly to the high-voltage without the use of a DC/DC converter module 28. The electrical loads 46 may have an associated controller that operates the electrical load 46 when appropriate. The low-voltage systems may be electrically connected to an auxiliary battery 30 (e.g., 12V battery).

The vehicle 12 may be an electric vehicle or a plug-in hybrid vehicle in which the traction battery 24 may be recharged by an external power source 36. The external power source 36 may be a connection to an electrical outlet. The external power source 36 may be electrically connected to electric vehicle supply equipment (EVSE) 38. The EVSE 38 may provide circuitry and controls to regulate and manage the transfer of energy between the power source 36 and the vehicle 12. The external power source 36 may provide DC or AC electric power to the EVSE 38. The EVSE 38 may have a charge connector 40 for plugging into a charge port 34 of the vehicle 12. The charge port 34 may be any type of port configured to transfer power from the EVSE 38 to the vehicle 12. The charge port 34 may be electrically connected to a charger or on-board power conversion module 32. The power conversion module 32 may condition the power supplied from the EVSE 38 to provide the proper voltage and current levels to the traction battery 24. The power conversion module 32 may interface with the EVSE 38 to coordinate the delivery of power to the vehicle 12. The EVSE connector 40 may have pins that mate with corresponding recesses of the charge port 34. Alternatively, various components described as being electrically connected may transfer power using a wireless inductive coupling.

One or more wheel brakes 44 may be provided for decelerating the vehicle 12 and preventing motion of the vehicle 12. The wheel brakes 44 may be hydraulically actuated, electrically actuated, or some combination thereof. The wheel brakes 44 may be a part of a brake system 50. The brake system 50 may include other components that work cooperatively to operate the wheel brakes 44. For simplicity, the figure depicts one connection between the brake system 50 and one of the wheel brakes 44. A connection between the brake system 50 and the other wheel brakes 44 is implied. The brake system 50 may include a controller to monitor and coordinate the brake system 50. The brake system 50 may monitor the brake components and control the wheel brakes 44 to decelerate or control the vehicle. The brake system 50 may respond to driver commands and may also operate autonomously to implement features such as stability control. The controller of the brake system 50 may implement a method of applying a requested brake force when requested by another controller or sub-function.

The various components discussed may have one or more associated controllers to control and monitor the operation of the components. The controllers may communicate via a serial bus (e.g., Controller Area Network (CAN)) or via discrete conductors. In addition, a system controller 48 may be present to coordinate the operation of the various components.

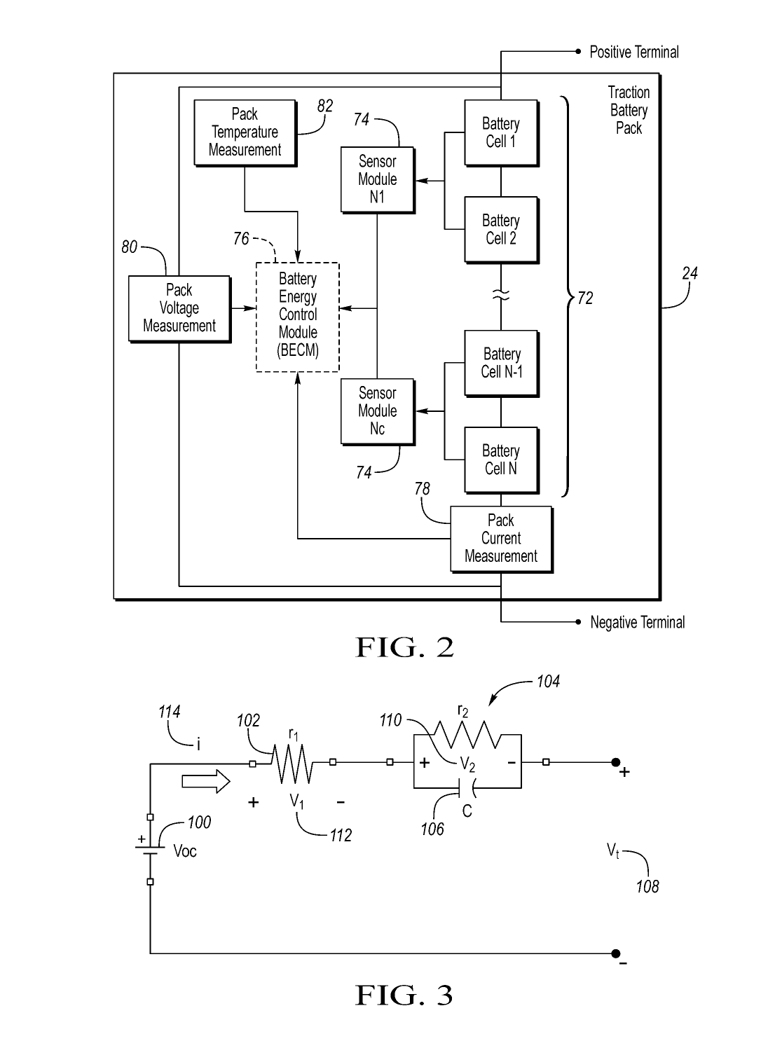

A traction battery 24 may be constructed from a variety of chemical formulations. Typical battery pack chemistries may be lead acid, nickel-metal hydride (NIMH) or Lithium-Ion. FIG. 2 shows a typical traction battery pack 24 in a simple series configuration of N battery cells 72. Other battery packs 24, however, may be composed of any number of individual battery cells connected in series or parallel or some combination thereof. A typical system may have a one or more controllers, such as a Battery Energy Control Module (BECM) 76 that monitors and controls the performance of the traction battery 24. The BECM 76 may monitor several battery pack level characteristics such as pack current 78, pack voltage 80 and pack temperature 82. The BECM 76 may have non-volatile memory such that data may be retained when the BECM 76 is in an off condition. Retained data may be available upon the next ignition cycle.

In addition to the pack level characteristics, there may be battery cell 72 level characteristics that are measured and monitored. For example, the terminal voltage, current, and temperature of each cell 72 may be measured. A system may use a sensor module 74 to measure the battery cell 72 characteristics. Depending on the capabilities, the sensor module 74 may measure the characteristics of one or multiple of the battery cells 72. The battery pack 24 may utilize up to N_{c} sensor modules 74 to measure the characteristics of each of the battery cells 72. Each sensor module 74 may transfer the measurements to the BECM 76 for further processing and coordination. The sensor module 74 may transfer signals in analog or digital form to the BECM 76. In some embodiments, the sensor module 74 functionality may be incorporated internally to the BECM 76. That is, the sensor module 74 hardware may be integrated as part of the circuitry in the BECM 76 and the BECM 76 may handle the processing of raw signals.

The battery cell 72 and pack voltages 80 may be measured using a voltage sensor. The voltage sensor circuit within the sensor module 74 and pack voltage measurement circuitry 80 may contain various electrical components to scale and sample the voltage signal. The measurement signals may be routed to inputs of an analog-to-digital (A/D) converter within the sensor module 74 and BECM 76 for conversion to a digital value. These components may become shorted or opened causing the voltage to be measured improperly. Additionally, these problems may occur intermittently over time and appear in the measured voltage data. The sensor module 74, pack voltage sensor 80 and BECM 76 may contain circuitry to ascertain the status of the voltage measurement components. In addition, a controller within the sensor module 74 or the BECM 76 may perform signal boundary checks based on expected signal operating levels.

The hardware sensor status may be ascertained by polling the measurement hardware of the sensor module 74 and the battery pack measurement circuitry 80. For example, an A/D converter may provide status data to indicate the success or failure of the conversion process. A controller 76 may periodically monitor the hardware status to determine if there is a hardware issue that prevents reliable signal conversion.

A hardware boundary check of the voltage measurement may be utilized to diagnose battery voltage sensor issues. For example, an extreme range of measured voltage values may be defined to diagnose shorts to power and ground. A diagnostic condition may be set whenever the cell or battery voltage is outside of the extreme range. This scheme tends to work well for detecting shorts to ground and power. However, this scheme may not work well for voltage measurement issues in which the measured voltage may be within the normal range of values (e.g., intermittent voltage spikes).

Signal boundary checks are a common technique of assessing signal validity. A measurement circuit may be designed such that extreme values are not typically possible. A cell voltage measurement may be normally constrained to be within a certain range of voltages. For example, a boundary check voltage range may be defined to be between 1.005 volts and 4.995 volts. Voltage measurements outside of this range may indicate a short to ground or short to power. A controller 76 may indicate a diagnostic flag when the voltage measurement is outside of the specified range for a predetermined period of time.

A disadvantage of these methods is that voltage fluctuations may not stray outside of the defined boundary check voltage range. A battery voltage measurement shorted to power or ground through a resistance may fall within the valid boundary check voltage range. In the case in which voltage spikes are present that do not go above or below the range, no issue will be flagged and inaccurate voltage data may be used in the controller. This may lead to inaccurate state of charge or battery capacity values.

A battery cell may be modeled as a circuit. FIG. 3 shows one possible battery cell equivalent circuit model (ECM). A battery cell may be modeled as a voltage source (V_{oc}) 100 having an associated impedance. The impedance may be comprised of one or more resistances (102 and 104) and a capacitance 106. V_{oc} 100 represents the open-circuit voltage of the battery. The model may include an internal resistance, r₁ 102, a charge transfer resistance, r₂ 104, and a double layer capacitance, C 106. The voltage V₁ 112 is the voltage drop across the internal resistance 102 due to current 114 flowing through the circuit. The voltage V₂ 110 is the voltage drop across the parallel combination of r₂ and C due to current 114 flowing through the combination. The voltage Vₜ 108 is the voltage across the terminals of the battery (terminal voltage).

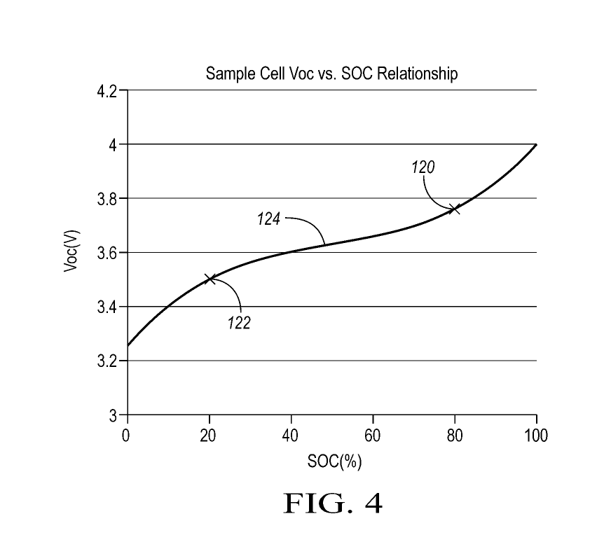

Because of the battery cell impedance, the terminal voltage, Vₜ 108, may not be the same as the open-circuit voltage, V_{oc} 100. The open-circuit voltage, V_{oc} 100, may not be readily measurable as only the terminal voltage 108 of the battery cell is accessible for measurement. When no current 114 is flowing for a sufficiently long period of time, the terminal voltage 108 may be the same as the open-circuit voltage 100. A sufficiently long period of time may allow the internal dynamics of the battery to reach a steady state. When current 114 is flowing, V_{oc} 100 may not be readily measurable and the value may be inferred based on the SOC as shown in FIG. 4. The parameter values, r₁, r₂, and C may be known or unknown. The value of the parameters may depend on the battery chemistry.

In a steady-state condition where currents and voltages are nearly constant, the capacitance 106 may not affect the circuit operation. In such a steady-state condition, the impedance of the equivalent circuit model may be modeled using the resistive components (102 and 104). The equivalent resistance in the steady-state condition may be expressed as a single resistance value that is the sum of r₁ 102 and r₂ 104.

The battery impedance parameters r₁ 102, r₂ 104, and C 106 may vary with the operating conditions of the battery. The values may vary as a function of the battery temperature. For example, the resistance values, r₁ 102 and r₂ 104, may decrease as temperature increases and the capacitance, C 106, may increase as the temperature increases. The impedance parameter values may also depend on the state of charge of the battery.

The battery impedance parameter values, r₁ 102, r₂ 104, and C 106 may also change over the life of the battery. For example, the resistance (102, 104) values may increase over the life of the battery. The increase in resistance may vary as a function of temperature and state of charge over the life of battery. Higher battery temperatures may cause a larger increase in battery resistance over time. For example, the resistance for a battery operating at 80C may increase more than the resistance of a battery operating at 50 C over a period of time. At a constant temperature, the resistance of a battery operating at 90% state of charge may increase more than the resistance of a battery operating at 50% state of charge. These relationships may be battery chemistry dependent.

For a typical Lithium-Ion battery cell, there is a relationship between SOC and the open-circuit voltage (V_{oc}) such that V_{oc}=f(SOC). FIG. 4 shows a typical curve 124 showing the open-circuit voltage V_{oc} as a function of SOC. The relationship between SOC and V_{oc} may be determined from an analysis of battery properties or from testing the battery cells. The exact shape of the curve 124 may vary based on the exact formulation of the Lithium-Ion battery. The voltage V_{oc} changes as a result of charging and discharging of the battery.

Since the battery impedance parameters may change over time and operating conditions, a system using constant values of the battery impedance parameters may inaccurately calculate other battery characteristics such as state of charge. In practice, it may be desirable to estimate the impedance parameter values during vehicle operation so that changes in the parameters will continually be accounted for. The equivalent circuit model may be utilized to estimate the various impedance parameters of the battery.

One possible model may be the equivalent circuit model of FIG. 3. The governing equations for the equivalent model may be written as:

$$\begin{matrix}{\dot{V}}_{2} = \frac{1}{{r}_{2} C} {V}_{2} + \frac{1}{C} * i & ( 1 ) \\ {V}_{t} = {V}_{oc} - {V}_{2} - {r}_{1} * i & ( 2 )\end{matrix}$$

where i is the current, and \dot{V}₂ is the time based derivative of V₂. The method proposed may be applied to both an individual battery cell and the battery pack. For a battery cell level application, the variables V_{oc}, Vₜ, V₂, r₁, r₂, and C may be parameters associated with the battery cell. For a battery pack level application, these variables may be parameters associated with the battery pack. For example, the battery pack level V_{oc} may be obtained by summing the individual cell values of V_{oc}.

Referring to the model of FIG. 3, various values may be measured on a per-cell basis or on an overall pack basis. For example, the terminal voltage, Vₜ 108, may be measured for each cell of the traction battery. The current, I 114, may be measured for the entire traction battery since the same current may flow through each cell. Different pack configurations may use different combinations of measurements. The estimation model may be performed for the entire battery pack or for each cell and the cell values may then be combined to arrive at an overall pack value.

The value of V_{oc} in equation (2) may be calculated based on the state of charge. The state of charge may be derived using an ampere-hour integration of the current 114. The open-circuit voltage 100 may then be calculated based on FIG. 4 from the state of charge value. An initial state of charge value may be found from FIG. 4 based on an open-circuit voltage reading after the battery has been resting for a sufficient amount of time.

The impedance parameter values may change overtime. One possible implementation may utilize an Extended Kalman Filter (EKF) to recursively estimate the parameter values. An EKF is a dynamic system, that is governed by equations of the following form:

xₖ=f(xₖ₋₁, uₖ₋₁, Wₖ₋₁) (3)

zₖ=h(xₖ, vₖ₋₁) (4)

where: xₖ may include the state V₂ and the other battery ECM parameters; uₖ is the input (e.g., battery current); wₖ is the process noise; zₖ may be the output (e.g., V_{oc}−Vₜ); and vₖ is the measurement noise.

One possible set of states for the governing equations for the equivalent model may be chosen as follows:

$$x = [ \begin{matrix}{x}_{1} \\ {x}_{2} \\ {x}_{3} \\ {x}_{4}\end{matrix} ] = [ \begin{matrix}{V}_{2} \\ 1 \text{/} ( {r}_{2} C ) \\ 1 \text{/} C \\ {r}_{1}\end{matrix} ] \qquad ( 5 )$$

Based on this choice of states, the discrete-time corresponding state space equations of equations (3) and (4) for the ECM model governed by equations (1) and (2) may be expressed in the form of Equations (6) and (7).

$$\begin{matrix}f ( {x}_{k} , {u}_{k} ) = [ \begin{matrix}( 1 - {T}_{s} {x}_{2} ( k ) ) {x}_{1} ( k ) + {T}_{s} {x}_{3} ( k ) i ( K ) \\ {x}_{2} \\ {x}_{3} \\ {x}_{4}\end{matrix} ] & ( 6 ) \\ h ( {x}_{k} , {u}_{k} ) = {x}_{1} ( k ) + {x}_{4} ( k ) i ( k ) & ( 7 )\end{matrix}$$

Based on the system model described, an observer, for example an EKF, may be designed to estimate the extended states (x₁, x₂, x₃ and x₄). Once the states are estimated, the voltage and impedance parameter values (V₂, r₁, r₂, and C) may be calculated as a function of the states as follows:

\hat{V}₂=x₁ (8)

\hat{r}₁=x₄ (9)

\hat{r}₂=x₃x₂ (10)

Ĉ=1/x₃ (11)

The complete set of EKF equations consists of time update equations and measurement update equations. The EKF time update equations project the state and covariance estimate from the previous time step to the current time step:

\hat{x}ₖ⁻=f(\hat{x}ₖ₋₁, uₖ₋₁) (12)

Pₖ⁻=AₖPₖ₋₁Aₖ^{T}+WₖQₖ₋₁Wₖ^{T} (13)

where: \hat{x}ₖ⁻ represents a priori estimate of xₖ; Pₖ⁻ represents a priori estimate error covariance matrix; Aₖ represents the Jacobian matrix of the partial derivatives of f(x, u, w) with respect to x; Pₖ₋₁ represents a posteriori estimate error matrix of last step; Aₖ^{T} represents transpose of matrix Aₖ; Wₖ represents the Jacobian matrix of the partial derivatives of f(x, u, w) with respect to process noise variable w; Qₖ₋₁ represents a process noise covariance matrix, and Wₖ^{T} represents transpose of matrix Wₖ.

The matrix Aₖ may be constructed from the set of state equations defined by equation (14). The input, u, in this case, may include the current measurement, i.

$${A}_{k} = [ \begin{matrix}1 - {T}_{s} {x}_{2} ( k ) & - {T}_{s} {x}_{1} ( k ) & {T}_{s} i ( k ) & 0 \\ 0 & 1 & 0 & 0 \\ 0 & 0 & 1 & 0 \\ 0 & 0 & 0 & 1\end{matrix} ] \qquad ( 14 )$$

The measurement update equations correct the state and covariance estimate with the measurement:

Kₖ=Pₖ⁻Hₖ^{T}(HₖPₖ⁻Hₖ^{T}+VₖRₖVₖ^{T})⁻¹ (15)

\hat{x}ₖ=\hat{x}ₖ⁻+Kₖ(zₖ−h(\hat{x}ₖ⁻, uₖ)) (16)

Pₖ=(I−KₖHₖ)Pₖ⁻ (17)

where: Kₖ represents the EKF gain; Hₖ represents the Jacobian matrix of the partial derivatives of h with respect to x; Hₖ^{T} is the transpose of Hₖ; Rₖ represents a measurement noise covariance matrix; Vₖ represents the Jacobian matrix of the partial derivatives of h with respect to measurement noise variable v; zₖ represents the measured output values; and Vₖ^{T} is the transpose of Vₖ.

In the EKF model, the resistance and capacitance parameters may be assumed to be slowly varying and have a derivative of approximately zero. The estimation objective may be to identify the time-varying values of the circuit parameters. In the above model, three impedance parameters may be identified: r₁, r₂, and C. More comprehensive models may additionally estimate V_{oc} as a time-varying parameter. Other model formulations may incorporate a second RC pair to represent a slow and a fast voltage recovery dynamics. These formulations may increase the number of states in the model.

One of ordinary skill in the art can construct and implement the EKF given a set of model equations. The system of equations described above is one example of a system model for a battery system. Other formulations are possible and the methods described will work equally well on other formulations.

In the above example, i and Vₜ may be measured quantities. The quantity V_{oc} may be derived from the state of charge which may be calculated using an ampere-hour integration of current 114. Once V2 and r1 are estimated, the battery terminal voltage may be estimated as:

\hat{V}ₜ=V_{oc}−\hat{V}₂−\hat{r}₁*i (18)

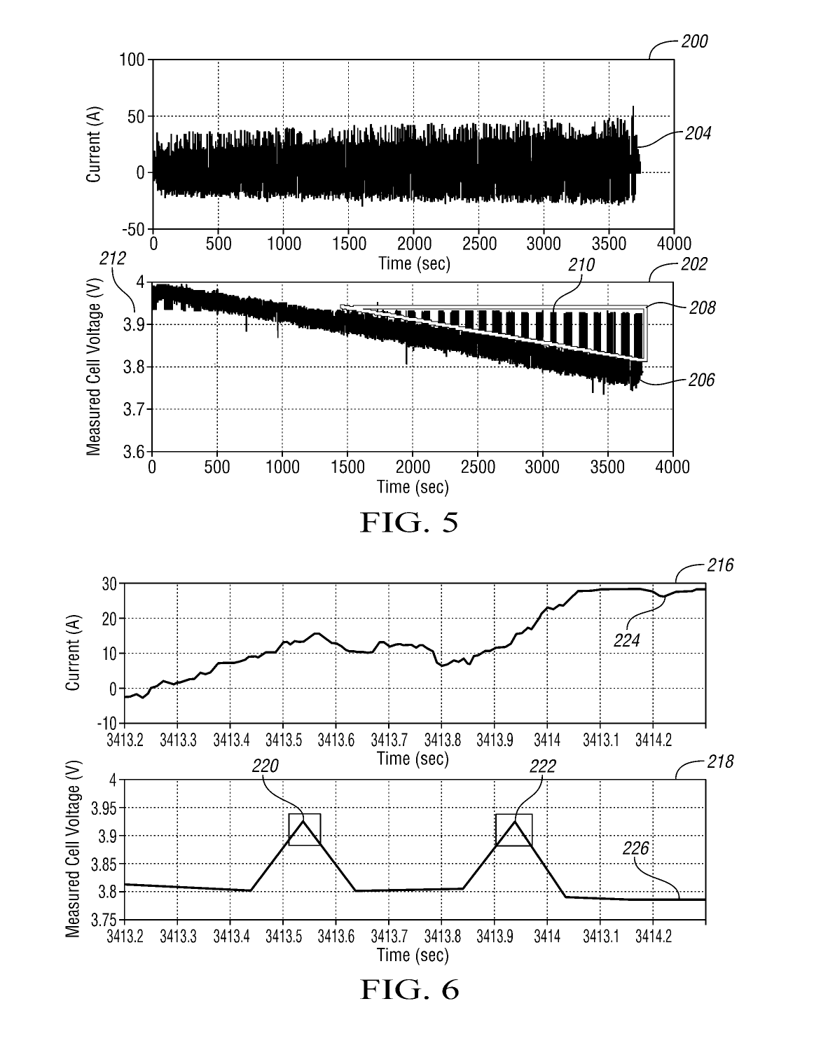

FIG. 5 depicts sample measurement data in which voltage measurement fluctuations are present but remain within the acceptable voltage range. A plot 200 of current 204 over time is shown along with a corresponding plot 202 of a measured cell voltage 206 over time. The plots 200, 202 may depict a condition in which the battery is mainly discharging. Note that over time, the voltage measurement curve 206 decays. As depicted, as the voltage measurement falls below an approximate threshold 212, pronounced voltage measurement fluctuations 210 occur that are at a greater voltage level than would be expected. Note that these voltage measurement fluctuations 210 may repeat over time as highlighted 208. The voltage measurement fluctuations 210 may occur intermittently over time and may not be predictable. The voltage measurement fluctuations 210 may be indicative of a problem with the battery cell or the associated voltage measurement circuitry. The voltage measurement fluctuations 210 may also be indicative of electromagnetic interference issues. The voltage measurement fluctuations are not limited to be increasing. A similar situation may exist in which the voltage fluctuations indicate a voltage drop.

FIG. 6 depicts a small time interval from the plot of FIG. 5. A plot 216 of current 224 over time and a corresponding plot 218 of measured voltage 226 over time are depicted over a small portion of the time range. Using this time scale, the voltage measurement fluctuations 220, 222 are more easily identified. In addition, it may be noticed that current 224 is positive during the time when the voltage measurement fluctuations 220, 222 are present. Normally, when current is positive (battery is supplying power to other loads or discharging) and the magnitude of the positive current increases, the measurement voltage may not be expected to increase. An abnormal condition may be ascertained during a condition in which the voltage measurement increases by more than a predetermined voltage when the battery is supplying power (e.g., current is positive or battery discharging). Should this abnormal condition be present, inaccurate voltage measurements may be received by the battery controller. The resulting voltage values calculated from the voltage measurements may be inaccurate leading to a reduction in vehicle performance and battery life.

It may desirable to detect the presence of a faulty voltage measurement that is within the boundary check voltage range. For example, a faulty voltage measurement may be the result of intermittent voltage spikes. A measurement of the battery current may be utilized to further confirm the presence of a voltage measurement diagnostic condition. The voltage measurement diagnostic condition may be further confirmed by non-matching current behavior coinciding with faulty voltage measurements. For example, a voltage measurement indicating a voltage increase while the current measurement indicates the battery is discharging with increasing discharge current magnitude or charging with decreasing charge current magnitude may indicate an inconsistent voltage measurement. As another example, a voltage measurement indicating a voltage decrease while the current measurement indicates the battery is discharging with decreasing discharge current magnitude or charging with increasing charge current magnitude may also indicate an inconsistent voltage measurement.

A comparison of the battery open circuit voltage, V_{oc}, with the battery terminal voltage, Vₜ, may be utilized to further confirm the presence of a voltage measurement diagnostic condition. The voltage measurement diagnostic condition may be further confirmed if V_{oc} is at least a predetermined amount greater than Vₜ while the battery is charging (e.g., battery is accepting power from an external power source) or if V_{oc} is at least a predetermined amount less than Vₜ while the battery is discharging (e.g., battery is supplying power to electrical loads). The battery open-circuit voltage may be expected to be greater than the terminal voltage during discharging. The battery open-circuit voltage may be expected to be less than the terminal voltage during charging.

A battery measurement diagnostic function may attempt to characterize these invalid in-range voltage measurements and set a diagnostic flag when voltage measurement issues are suspected due to an abnormal hardware condition. The diagnostic function may prevent false indications by allowing some voltage fluctuations but not more than a predetermined number. When the number of detected voltage fluctuations exceeds the predetermined number, a diagnostic flag may be output.

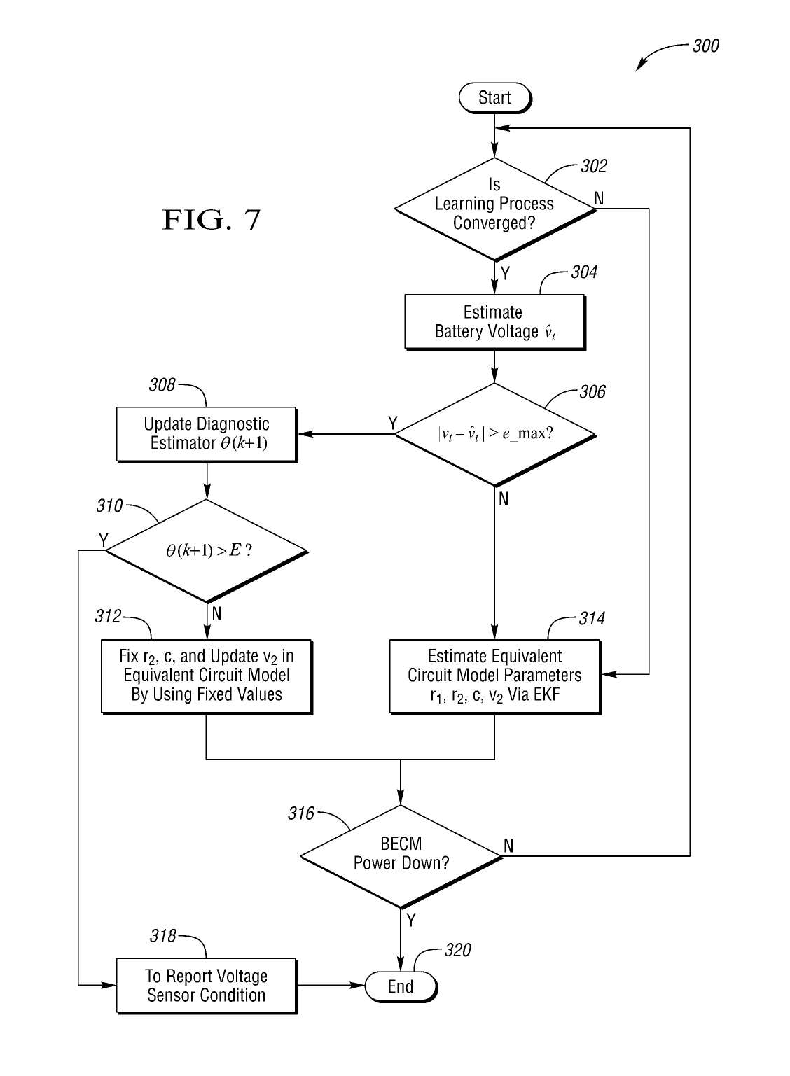

FIG. 7 depicts a possible flowchart for a battery measurement diagnostic system 300 to diagnose battery voltage sensor issues. The EKF described above or some other estimation scheme may be implemented in a controller and used to generate impedance parameter estimates. The first step 302 in diagnosing voltage measurement issues may be to check if the estimation model has converged. This may indicate that the parameter estimates are close to the actual values. Convergence may be checked by comparing a model output with a measured value. If the magnitude of the difference between the model output and the measured value is below a predetermined value over a predetermined period of time, then the estimates may be considered to have converged. For example, the measured terminal voltage and an estimated terminal voltage may be used.

If the parameter estimation has converged, an estimated terminal voltage may be calculated from the impedance parameter estimates 304. The terminal voltage of the cell or pack may be calculated according to equation (18) using the estimated states from the EKF. The V_{oc} value may be derived as a function of SOC or may be estimated as part of the estimation model.

A magnitude of a difference between the measured terminal voltage and the estimated terminal voltage may be calculated and compared to a threshold 306. If the magnitude of the difference is greater than a predetermined threshold, e_max, then an abnormal voltage measurement may be present. In this case, a diagnostic estimator, θ, may be updated 308. The diagnostic estimator may be a counter that accumulates the number of time steps in which the difference magnitude exceeds the predetermined magnitude. The diagnostic estimator may be incremented each time the magnitude of the difference is greater than the predetermined threshold, e_max. The diagnostic estimator may maintain a cumulative count of the number of time steps in which the difference magnitude exceeds the predetermined threshold. Alternatively, the diagnostic estimator may be decremented or reset when the difference magnitude is less than the predetermined threshold.

The update procedure may be expressed in equation form as follows.

$$\begin{matrix}θ ( k + 1 ) = θ ( k ) + D ( \vert {v}_{t} - {\hat{v}}_{t} \vert ) & ( 19 ) \\ where & \\ D ( {v}_{t} - {\hat{v}}_{t} ) = \{ \begin{matrix}0 , \vert {v}_{t} - {\hat{v}}_{t} \vert \leq e \_max \\ 1 , \vert {v}_{t} - {\hat{v}}_{t} \vert > e \_max\end{matrix} & ( 20 )\end{matrix}$$

The diagnostic estimator, θ, may be compared to a threshold 310. When the diagnostic estimator, θ, is greater than a calibratable value, E, a battery voltage measurement diagnostic flag may be reported 310. The voltage measurement diagnostic flag may be used to alert an operator that there is an issue. The voltage measurement diagnostic flag may also trigger storage of a diagnostic code in non-volatile memory for later retrieval.

The diagnostic estimator may be incremented based on the difference indicating a change in voltage different than expected based on the change in current. For example, under normal conditions, a rising voltage may be the result of an increasing charge current (e.g., current flow into the battery) or a decreasing discharge current (e.g., current flow from the battery). The measured current may actually indicate a decreasing charge current or an increasing discharge current. The increment condition for the diagnostic estimator may be qualified by the non-matching behavior of the voltage difference and the measured current. When the changes in the voltage and current measurements do not match, it may be more likely that there is a voltage measurement diagnostic condition present.

The diagnostic estimator may also be incremented based on the mismatch between the battery open circuit and the battery terminal voltage for the predetermined number of time steps. For example, the diagnostic indicator may be incremented when the battery is discharging and the open-circuit voltage is less than the terminal voltage. The diagnostic indicator may also be incremented when the battery is charging and the open-circuit voltage is greater than the terminal voltage.

When the diagnostic estimator, θ, is not yet greater than the calibratable value, E, the battery voltage estimation may continue operating. In this case, the system may fix the impedance parameter values 312 rather than using the impedance parameter estimates from the current time step. The system may fix the impedance parameter values to impedance parameter values from selected previous time step in which the difference magnitude was less than the predetermined threshold. The selected previous time step may be the most recent time step in which the difference magnitude was less than the predetermined threshold. The EKF equation for estimating V₂ may be expressed as:

$${v}_{2} ( k + 1 ) = ( 1 - \frac{{T}_{s}}{{r}_{2} ( k - n ) C ( k - n )} ) {v}_{2} ( k ) + \frac{{T}_{s}}{C ( k - n )} i ( k ) \qquad ( 21 )$$

where the value n is an integer greater than or equal to zero such that

|vₜ(k−n)−\hat{v}ₜ(k−n)|≦e_max (22)

The controller may use the estimated impedance parameter values from the last execution interval in which the voltage measurement did not exhibit any voltage measurement diagnostic conditions. In this condition, the impedance parameters may be temporarily frozen because any attempt to estimate the impedance parameters may be inaccurate due to the abnormal voltage measurement. In addition to freezing the values, the system may temporarily suspend executing the parameter estimation algorithm.

If the magnitude of the difference is less than the predetermined threshold, e_max, then the voltage measurement may be operating correctly. In this case, the system may continue estimating the impedance parameters using the EKF as described 314. Parameters may be estimated using an EKF and voltages may be estimated using the estimated impedance parameters.

The described logic may be executed while the controller is powered up. A controller power-down condition may be checked 316. The controller may be considered powered up during an ignition cycle (e.g., key in ignition). Further, as a battery controller may operate during other conditions, the power up condition may be considered to be anytime during which the battery controller is active. The logic may stop executing 320 when the battery controller has powered down.

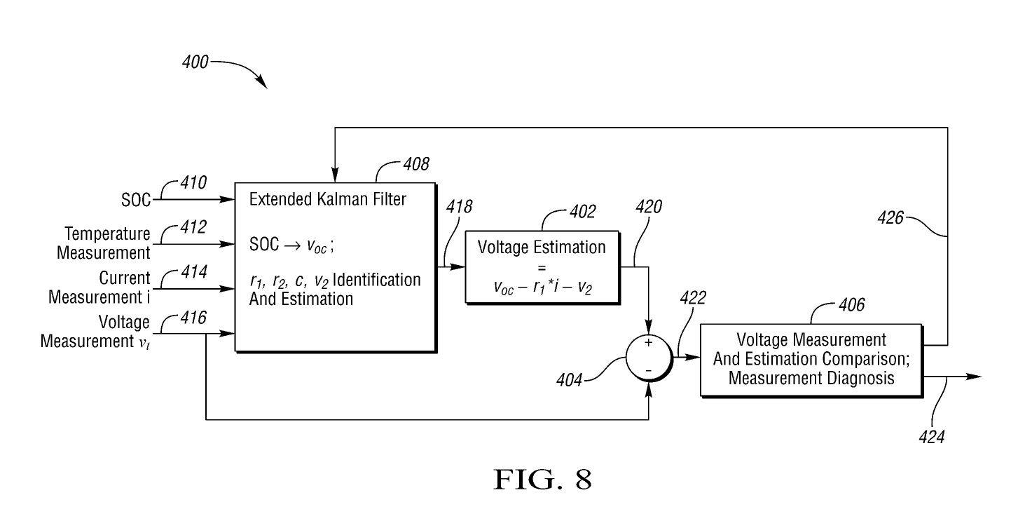

FIG. 8 depicts a block diagram of a battery voltage measurement diagnosis system 400. The system may implement an extended Kalman filter 408 to estimate impedance parameters and system voltages. Inputs to the filter may be SOC 410, a battery temperature 412, a measured battery current 414, and a battery voltage measurement 416. The battery voltage measurement 416 may be a cell voltage or an overall pack voltage. An additional input 426 may be an input that indicates that impedance parameters should not be updated during the present time step. The additional input 426 may also indicate that the impedance parameters should be fixed at a previous value. The output 418 of the filter 408 may be the estimated impedance parameters and estimated system voltages. These values may be input to a voltage estimator 402 which may output an estimation of the battery or cell terminal voltage 420. A summing element 404 may provide an output 422 that is the difference between the estimated voltage and the measured voltage. The difference may then be processed 406 as described previously. A magnitude of the difference may be compared to a predetermined threshold. If the magnitude is above the predetermined threshold for more than a predetermined time or number of time steps, a voltage measurement diagnostic 424 may be output. In addition, an output signal 426 may be output when the magnitude is greater than the predetermined threshold for fixing the impedance parameters at previous values.

The scheme described may improve performance of the parameter estimation scheme by inhibiting parameter estimation when there is an anomaly in the voltage measurements. Conditions such as voltage measurement spikes may not be readily detectable by existing diagnostic functions. The detection scheme may be implemented with extra hardware elements in the controller. Vehicle and battery performance may be enhanced by this additional processing of the voltage measurement.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A vehicle comprising:
a traction battery including a plurality of cells; and
at least one controller programmed to (i) output impedance parameters based on a measured voltage at a plurality of time steps while a magnitude of a difference between the measured voltage and an impedance parameter based estimated voltage is less than a predetermined value, and (ii) otherwise, output impedance parameters based on impedance parameter estimates from a selected previous one of the time steps.

2. The vehicle of claim 1 wherein the at least one controller is further programmed to, in response to the magnitude of the difference between the measured voltage and the impedance parameter based estimated voltage being greater than the predetermined value for greater than a predetermined number of time steps, output a diagnostic flag.

3. The vehicle of claim 1 wherein the selected previous one of the time steps is a most recent time step in which the magnitude of the difference between the measured voltage and the impedance parameter based estimated voltage is less than the predetermined value.

4. The vehicle of claim 1 wherein the at least one controller is further programmed to output impedance parameters further based on a measured current.

5. The vehicle of claim 4 wherein the at least one controller is further programmed to output impedance parameters based on impedance parameter estimates from the selected previous one of the time steps while the magnitude is greater than the predetermined value and the difference indicates a voltage change different than an expected voltage change indicated by a change in the measured current.

6. A vehicle comprising:
a traction battery including a plurality of cells; and
at least one controller programmed to, in response to a magnitude of a difference between a measured cell voltage and an impedance parameter based estimated cell voltage at each of a plurality of time steps being greater than a predetermined value for a predetermined number of the time steps, output a diagnostic flag.

7. The vehicle of claim 6 wherein the predetermined number of the time steps are non-consecutive.

8. The vehicle of claim 6 wherein the at least one controller is further programmed to estimate impedance parameters at the plurality of time steps based on the measured cell voltage while the difference is less than the predetermined value.

9. The vehicle of claim 6 wherein the at least one controller is further programmed to estimate impedance parameters at the plurality of time steps based on impedance parameters from a selected previous one of the time steps while the difference is greater than the predetermined value.

10. The vehicle of claim 9 wherein the selected previous one of the time steps is a most recent time step in which the difference is less than the predetermined value.

11. The vehicle of claim 6 wherein the at least one controller is further programmed to estimate impedance parameters and the estimated cell voltage based on an equivalent circuit model of the cells.

12. The vehicle of claim 6 wherein the at least one controller is further programmed to output the diagnostic flag further in response to the difference indicating a voltage change different than an expected voltage change indicated by a change in a measured current for the predetermined number of the time steps.

13. A method of battery voltage estimation, comprising:
measuring, by a controller, a voltage at a plurality of time steps;
outputting an estimated voltage based on impedance parameter estimates while a difference magnitude between the voltage and the estimated voltage is less than a predetermined value; and
outputting the estimated voltage based on impedance parameters from a selected previous one of the time steps while the difference magnitude is greater than the predetermined value.

14. The method of claim 13 further comprising outputting a diagnostic flag in response to the difference magnitude being greater than the predetermined value for a predetermined number of the time steps.

15. The method of claim 13 wherein the impedance parameter estimates are based on the voltage while the difference magnitude is less than the predetermined value.

16. The method of claim 13 further comprising measuring a battery current, wherein the impedance parameter estimates are further based on the battery current while the difference magnitude is less than the predetermined value.

17. The method of claim 16 further comprising outputting the estimated voltage based on impedance parameter estimates from the selected previous one of the time steps while the difference magnitude is greater than the predetermined value and the difference indicates a voltage change different than an expected voltage change indicated by a change in the battery current.

18. The method of claim 13 wherein the selected previous one of the time steps is a most recent one of the time steps in which the difference magnitude is less than the predetermined value.

19. The method of claim 13 further comprising estimating the impedance parameters and estimating the voltage at the plurality of time steps based on an equivalent circuit model of the battery.

20. The method of claim 13 further comprising outputting a diagnostic flag in response to at least one of a battery open-circuit voltage being less than the voltage for a predetermined number of time steps during discharging and the battery open-circuit voltage being greater than the voltage for a predetermined number of time steps during charging.
